(19) United States
(12) Patent Application Publication
(10) Pub. No.: US 2026/0354122 A1
(43) Pub. Date: Nov. 5, 2026

(54) METHOD OF MANUFACTURING ELECTRONIC DEVICE

(71) Applicant: Advanced Semiconductor Engineering, Inc., Kaohsiung (TW)

(72) Inventor: Juergen Bruegl, Munich (DE)

(73) Assignee: Advanced Semiconductor Engineering, Inc., Kaohsiung (TW)

(21) Appl. No.: 19/199,324

(22) Filed: May 5, 2025

(51) Int. Cl. H10P 74/00

(52) U.S. Cl. CPC H10P 74/238

(57) ABSTRACT

The present disclosure provides a method of manufacturing an electronic device. The method includes: performing a first test measuring first electrical properties of a plurality of dies; selecting a first group of the plurality of dies based on the first electrical properties of the plurality of dies; treating the first group of the plurality of die; and packaging the plurality of dies.

### BACKGROUND

### 1. Technical Field

The present disclosure relates to a method of manufacturing an electronic device.

### 2. Description of the Related Art

In electric vehicles, DC/AC converters are used to transform the typical 400V to 800V DC battery voltage into alternating current to drive the electric motors. These inverters generally employ a three-phase half-bridge configuration, meaning each inverter contains at least six high-power switching elements, typically MOSFETs, such as silicon carbide MOSFETs. The discrepancy in the electrical characteristics of the inverters negatively impacts the performance of electronic devices. Consequently, a novel approach to device design is necessary.

### SUMMARY

In some arrangements, a method of manufacturing an electronic device includes: performing a first test measuring first electrical properties of a plurality of dies; selecting a first group of the plurality of dies based on the first electrical properties of the plurality of dies; treating the first group of the plurality of die; and packaging the plurality of dies.

In some arrangements, a method of manufacturing an electronic device includes: obtaining electrical properties of a plurality of dies; obtaining threshold values based on the electrical properties; and modifying at least one of the electrical properties of a first group of the plurality of dies when the at least one of the electrical properties exceeds a corresponding one of the threshold values.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1 is a flowchart of a method for manufacturing an electronic device according to various aspects of the present disclosure.

FIG. 2 is a flowchart of a method for manufacturing an electronic device according to various aspects of the present disclosure.

FIG. 3 is a flowchart of a method for manufacturing an electronic device according to various aspects of the present disclosure.

FIG. 4 is a flowchart of a method for manufacturing an electronic device according to various aspects of the present disclosure.

FIG. 5 is a flowchart of a method for manufacturing an electronic device according to various aspects of the present disclosure.

FIG. 6, FIG. 7, FIG. 8, and FIG. 9 illustrate various stages in the formation of an electronic device, in accordance with some embodiments of the present disclosure.

FIG. 10 is a flowchart of a method for manufacturing an electronic device according to various aspects of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

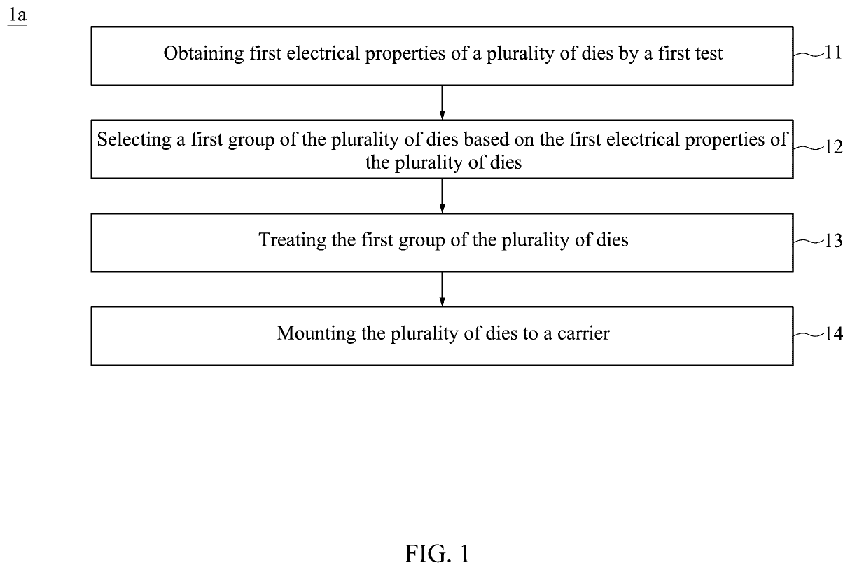

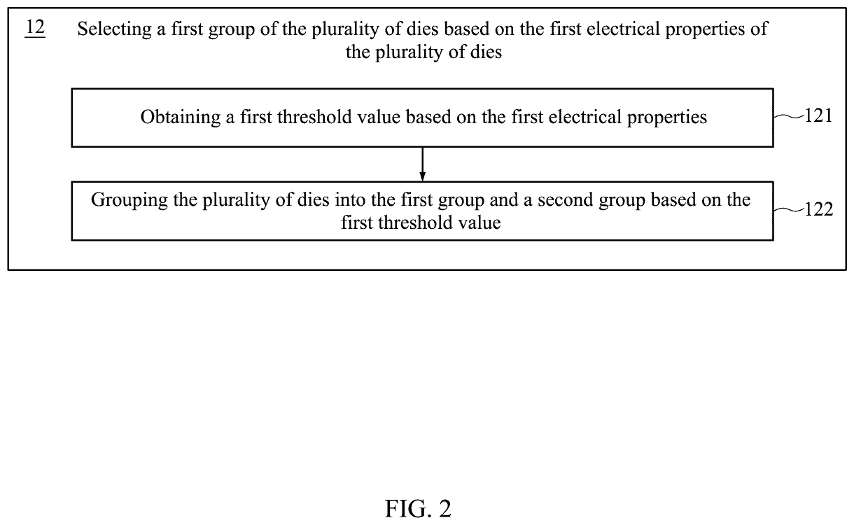

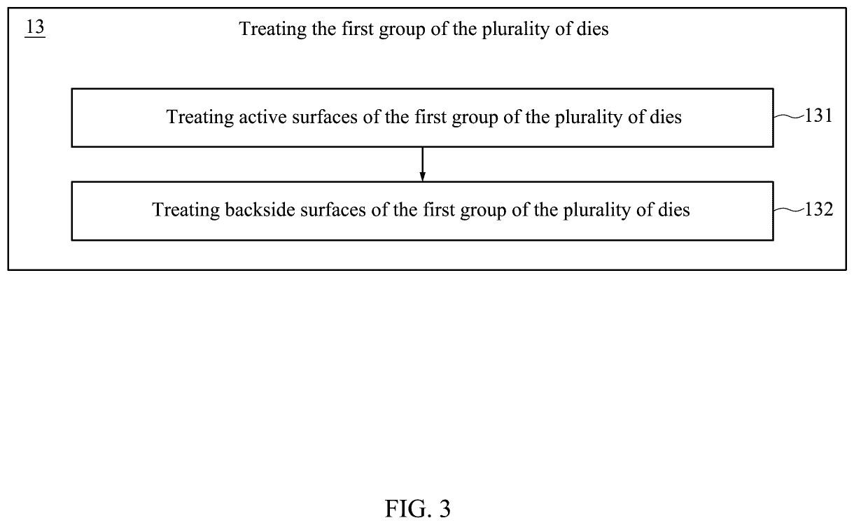

FIGS. 1-3 are flowcharts of a method 1a for manufacturing an electronic device according to various aspects of the present disclosure. In some arrangements, the method 1a includes operations 11, 12, 13, and 14. The method 1a may be configured to test and modify electrical properties (e.g., on-resistance (R_{dson}), threshold voltage (V_{GSth}), or other electrical properties) of a metal-oxide-semiconductor field-effect transistor (MOSFET), such as a silicon carbide MOSFET (SiC-MOSFET) or other MOSFETs. In some arrangements, the method 1a may be configured to test and modify electrical properties of a singulated die or a die remaining within a wafer. After the electrical properties of the dies are fine-tuned, the dies may be configured to define an electronic device or a part of an electronic device. For example, the dies may be configured to define an inverter, such as a three phase half-bridge inverter.

The method 1a begins with the operation 11 in which first electrical properties of a plurality of dies are obtained by a first test. In some arrangements, the dies may be tested in a die level, a wafer level, or a system level. In some arrangements, the first electrical properties may include on-resistance, threshold voltage, or other suitable electrical properties. In some arrangements, the first test may be performed at a room temperature, such as a temperature ranging from 15 °C to 30 °C. The first test may be performed by known equipment and methods, and the present disclosure is not intended to be limiting. In this arrangement, the term “first electrical property” may refer to on-resistance, threshold voltage, or other suitable electrical properties that are measured at a room temperature.

The method 1a continues with the operation 12 in which a first group of the plurality of dies is selected based on the first electrical properties of the plurality of dies. The operation 12 may include operations 121 and 122.

The operation 121 includes obtaining a first threshold value based on the first electrical properties. In some arrangements, the first threshold value may be configured to determine whether a die requires treatment. For example, when the on-resistance, threshold voltage, or both of a die exceeds the first threshold value, said die will be treated, and when the on-resistance, threshold voltage, or both of a die does not exceed the first threshold value, said die will remain untreated. In some arrangements, the average (A1) and the standard deviation (D1) of the first electrical properties of the plurality of dies may be obtained. In some arrangements, the first threshold value(s) may be set as A1 ±1 D1, A1±1.5 D1, A1±2 D1. In this disclosure, the average (A1) may include the average of the on-resistance, the average threshold voltage, and the average of other electrical properties that are measured at the room temperature. In this disclosure, the standard deviation (D1) may include the standard deviation of the on-resistance, the standard deviation of the threshold voltage, and the standard deviation of other electrical properties. The dataset used to calculate average (A1) and the standard deviation (D1) may be obtained from the dies that are measured at the same measurement or from the database including multiple measurements.

The operation 122 includes grouping the plurality of dies into the first group and a second group based on the first threshold value(s). For example, in the case that the first threshold value(s) is set as A1±1 D1 , when the on-resistance, threshold voltage, or both of a die fall outside A1+1 D1, said die is grouped into the first group, and when the on-resistance, threshold voltage, or both of a die is within A1±1 D1 , said die is grouped into the second group.

The method 1a continues with the operation 13 in which the first group of the plurality of dies are treated. The operation 13 may include operations 131 and 132.

The operation 131 includes treating active surfaces of the first group of the plurality of dies. In some arrangements, a plasma activated laser process (PALP) may be performed to treat the active surfaces of the first group of the plurality of dies. In some arrangements, the PALP may be configured to clean and/or modify the active surfaces of the dies. In some arrangements, the PALP may be configured to damage or reconstruct the structures or layers or atoms abutting the active surfaces of the dies. In some arrangements, the profile and/or concentration of the doped regions of a die (or MOSFET) may be fine-tuned in the operation 131. In some arrangements, the dimension (the thickness or width) of the gate dielectric and/or gate electrode may be fine-tuned in the operation 131. In some arrangements, the dimension (the thickness or width) of the spacer, which is disposed on the sidewall of the gate electrode, may be fine-tuned in the operation 131. In this disclosure, the term “active surface” may refer to a surface on which the MOSFET is formed. In some arrangements, the second group of the plurality of dies are untreated in the operation 131.

The operation 132 includes treating backside surfaces of the first group of the plurality of dies. In some arrangements, the PALP or other suitable processes may be performed to treat the backside surfaces of the first group of the plurality of dies. For example, the thickness of the substrate (e.g., SiC or Si) or the thickness of a partial region of the substrate may be modified. In this disclosure, the term “backside surface” may refer to a surface opposite to the active surface. In some arrangements, the second group of the plurality of dies are untreated in the operation 132. In some arrangements, the sequence of the operations 131 and 132 may be interchanged.

The method 1a continues with the operation 14 in which the plurality of dies are mounted to a carrier. In some arrangements, the dies, including treated first group and untreated second group, are mounted to a carrier. The carrier may include a printed circuit board (PCB), flexible printed circuit board (FPCB), lead frame, a combination thereof, or other suitable circuit structures. In some arrangements, the first group and second group of the plurality of dies may define, form, or constitute an inverter, such as three phase half-bridge inverter, or other suitable circuits. For example, the plurality of dies may include six dies that define, form, or constitute a three phase half-bridge inverter.

In a comparative example, the electrical properties of the dies (or MOSFETs) are not treated. Misalignment or deviation of the dies can lead to undesirable thermal imbalances and increased power loss. In the present arrangements, the outlier dies (or MOSFETs) are specifically treated. As a result, the dies exhibit more consistent on-resistance, threshold voltage, and other electrical characteristics. Consequently, thermal imbalance is minimized, and power loss is reduced.

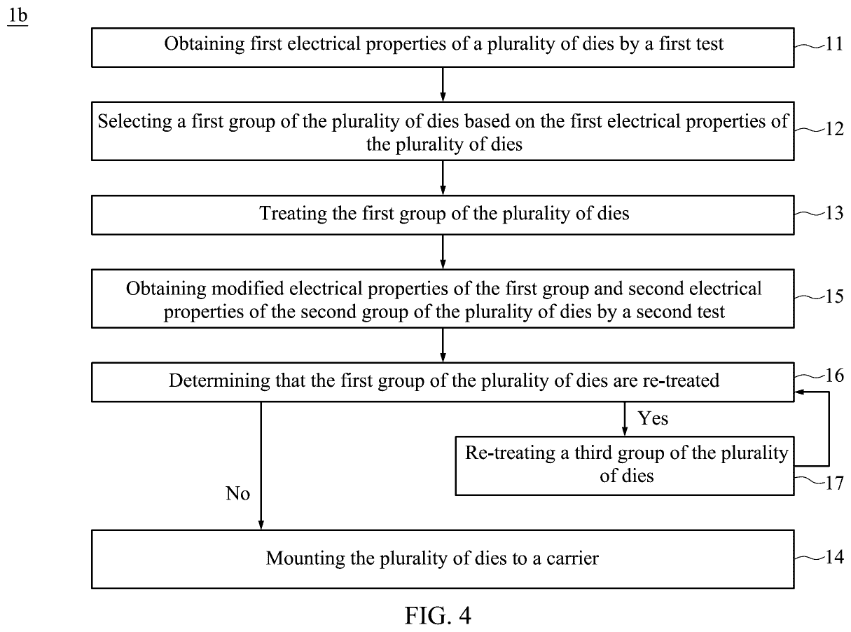

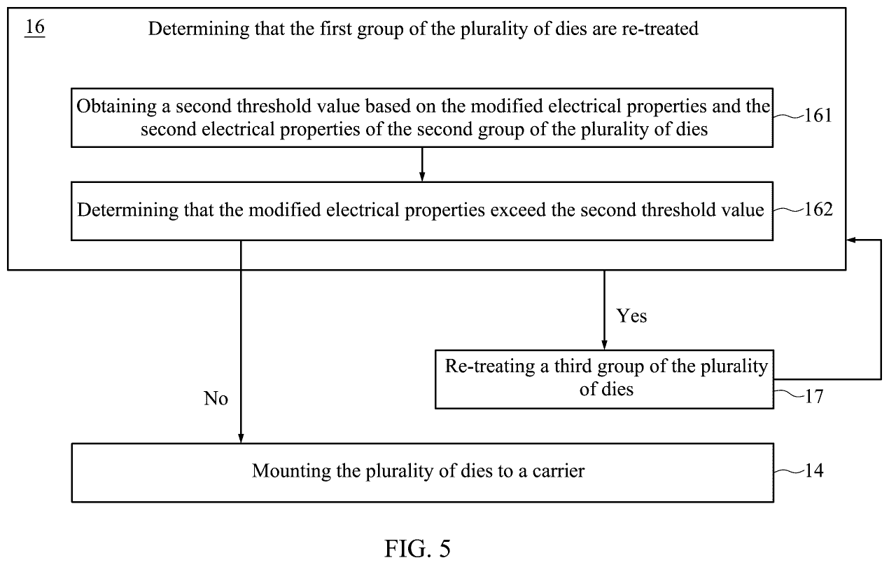

FIGS. 4 and 5 are flowcharts of a method 1b for manufacturing an electronic device according to various aspects of the present disclosure. The method 1b is similar to the method 1a except that the method 1b further includes operations 15, 16, and 17.

The operation 15 may follow the operation 13. The operation 15 may include obtaining modified electrical properties of the first group and second electrical properties of the second group of the plurality of dies by a second test. In some arrangements, the modified electrical properties may include on-resistance, threshold voltage, or other suitable electrical properties. In some arrangements, the second electrical properties may include on-resistance, threshold voltage, or other suitable electrical properties. In some arrangements, the second test may be performed at a temperature greater than a room temperature. In some arrangements, the second test may be performed at a temperature ranging from 100 °C to 200 °C. The second test may be performed by known equipment and methods, and the present disclosure is not intended to be limiting. In this arrangement, the terms “second electrical property” and “modified electrical properties” may refer to on-resistance, threshold voltage, or other suitable electrical properties that are measured at a temperature ranging from 100 °C to 200 °C.

The method 1b may continue with the operation 16 including determining that the first group of the plurality of dies requires re-treatment. When a die from the first group is determined to be re-treated, the operation 17 follows the operation 16. When a die from the first group is determined not to be re-treated, the operation 14 follows the operation 16. The operation 16 may include operations 161 and 162.

The operation 161 includes obtaining a second threshold value(s) based on the modified electrical properties and the second electrical properties of the second group of the plurality of dies. In some arrangements, the second threshold value(s) may be determined by the dataset including the modified electrical properties and the second electrical properties. In some arrangements, the second threshold value(s) may be determined by the dataset that includes the second electrical properties while excludes the modified electrical properties. In some arrangements, the second threshold value(s) may be configured to determine whether a die from the first group requires re-treatment. For example, when the on-resistance, threshold voltage, or both of a die exceeds the second threshold value, said die will be re-treated, and when the on-resistance, threshold voltage, or both of a die does not exceed the second threshold value, said die is determined not to be re-treated. In some arrangements, the average (A2) and the standard deviation (D2) of the plurality of dies may be obtained. In some arrangements, the second threshold value(s) may be set as A2±1 D2, A2±1.5 D2, A2±2 D2. In this disclosure, the average (A2) may include the average of the on-resistance, the average threshold voltage, and the average of other electrical properties that are measured at a temperature ranging from 100 °C to 200 °C. In this disclosure, the standard deviation (D2) may include the standard deviation of the on-resistance, the standard deviation of the threshold voltage, and the standard deviation of other electrical properties. The dataset used to calculate the average (A2) and the standard deviation (D2) may be obtained from the dies that are measured at the same measurement or from the database including multiple measurements.

The operation 162 includes determining that the modified electrical properties exceed the second threshold value. For example, in the case that the second threshold value(s) is set as A2±1 D2 , when the on-resistance, threshold voltage, or both of a die from the first group fall outside A2±1 D2 , said die is determined to be re-treated, and when the on-resistance, threshold voltage, or both of a die from the first group is within A2±1 D2 , said die is determined not to be re-treated. In some arrangements, a portion of the first group of the plurality of dies are determined to be re-treated and may be grouped into a third group. In some arrangements, a portion of the first group of the plurality of dies are determined not to be re-treated and may be grouped into a fourth group.

In some arrangements, the operation 17 includes re-treating the third group of the plurality of dies. In some arrangements, re-treating the third group of the plurality of dies includes treating active surfaces of the third group of the plurality of dies which is similar to or the same as the operation 131. In some arrangements, re-treating the third group of the plurality of dies includes treating backside surfaces of the third group of the plurality of dies which is similar to or the same as the operation 132. In some arrangements, the second group and the fourth group of the plurality of dies remain untreated in the operation 17. After the operation 17 is performed, the operation 16 may follow the operation 17 to determine whether further re-treatment is necessary, until the electrical properties meet the desired criteria. The re-treated third group of the plurality of dies are tested to determine whether a re-treating is performed.

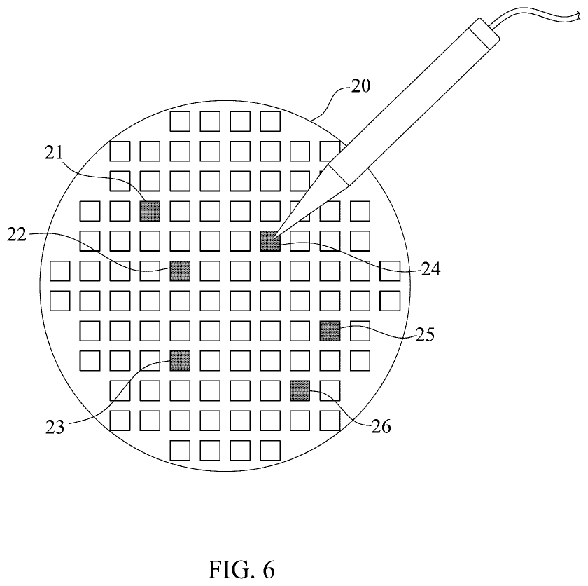

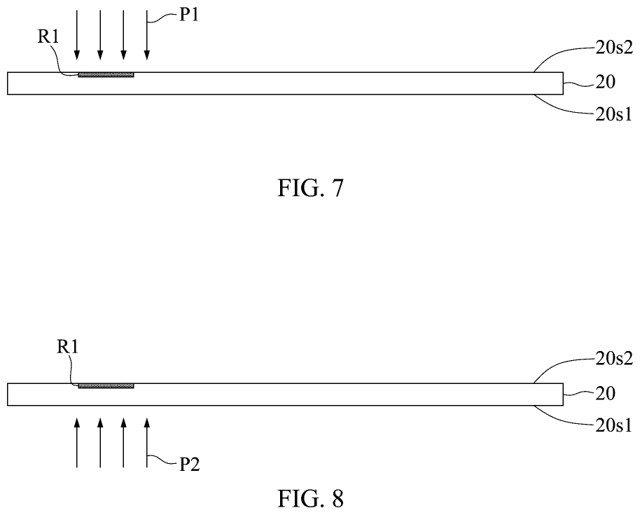

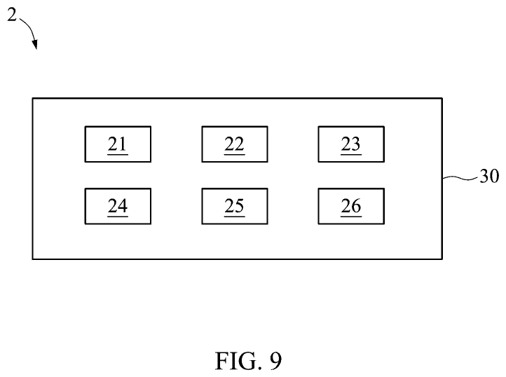

FIG. 6, FIG. 7, FIG. 8, and FIG. 9 illustrate various stages in the formation of an electronic device 2, in accordance with some embodiments of the present disclosure.

Referring to FIG. 6, a wafer 20 may be provided. The wafer 20 may include a plurality of dies. For example, the wafer 20 may include dies 21, 22, 23, 24, 25, 26, and other dies (not labeled). In some arrangements, a first test may be performed on the dies 21 to 26. In some arrangements, the on-resistance, threshold voltage, and other electrical properties of the dies 21 to 26 are obtained. In some arrangements, the dataset used to calculate on-resistance, threshold voltage, and other electrical properties is obtained from merely the dies 21 to 26. In some arrangements, the dataset used to calculate on-resistance, threshold voltage, and other electrical properties is obtained from all of the dies of the wafer 20 as well as the dies from other wafers. In some arrangements, the dies 21 to 26 are selected to define or constitute a three phase half-bridge inverter. The operations 11 and 12 may correspond to the stage as shown in, for example, FIG. 6.

Referring to FIG. 7, the wafer 20 may have a backside surface 20s1 and an active surface 20s2 opposite to the backside surface 20s1. In some arrangements, a treatment P1 may be performed on the active surface 20s2 of the wafer 20. In some arrangements, the treatment P1 may be performed on a region R1 of the active surface 20s2 of the wafer 20. The region R1 may correspond to the locations of the dies that are determined to be treated. In some arrangements, areas outside of region R1 are not treated. The operation 131 may correspond to the stage as shown in, for example, FIG. 7. In some arrangements, a portion of the dies 21 to 26 are treated under the treatment P1. In some arrangements, the treatment P1 may be performed on a wafer or a singulated die.

Referring to FIG. 8, a treatment P2 may be performed on the backside surface 20s1 of the wafer 20. In some arrangements, the treatment P2 may be performed on the region R1 of the backside surface 20s1 of the wafer 20. In some arrangements, areas outside of region R1 are not treated. The operation 132 may correspond to the stage as shown in, for example, FIG. 8. In some arrangements, a portion of the dies 21 to 26 are treated under the treatment P2. In some arrangements, the treatment P2 may be performed on a wafer or a singulated die.

Referring to FIG. 9, the dies 21 to 26 may be mounted to a carrier 30. An electronic device 2 may be produced. The carrier 30 may include a printed circuit board (PCB), flexible printed circuit board (FPCB), lead frame, a combination thereof, or other suitable circuit structures. Since a portion of the dies 21 to 26 may be treated, the dies 21 to 26 may have similar electrical properties. Therefore, the electronic device 2 may have a less power loss compared to a traditional device.

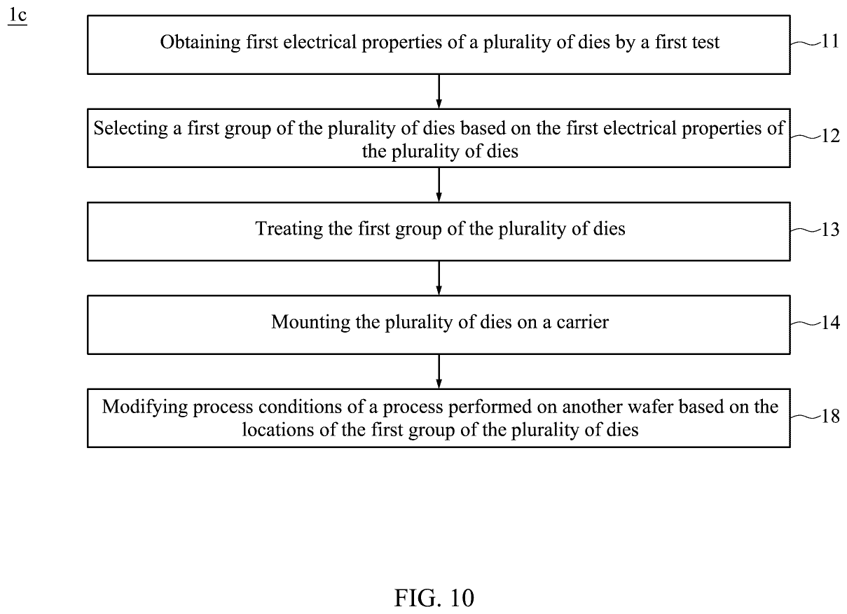

FIG. 10 is a flowchart of a method 1c for manufacturing an electronic device according to various aspects of the present disclosure. The method 1c is similar to the method 1a except that the method 1c further includes an operation 18.

In some arrangements, the operation 18 may follow the operation 14. In some arrangements, the operation 18 may follow the operation 13. In some arrangements, the operation 18 may follow the operation 12. The operation 18 may include modifying process conditions of a process performed on another wafer (or second wafer) based on the locations of the first group of the plurality of dies. In some arrangements, when the first electrical properties of the plurality of dies on the wafer are obtained, the locations of the dies that are determined to be treated are obtained. In this condition, the process conditions performed on the next wafer may be modified. In some arrangements, the process conditions may include temperature, pressure, process time, power, or other parameters that define a recipe of a process which is performed to form a gate dielectric, gate electrode, doped region, or other elements or performed to remove layers, such as gate dielectric, gate electrode, doped region, or other elements. The operation 18 may be configured to align or substantially equalize the electrical properties of dies at different locations, thereby reducing the number of dies treated that have electrical properties exceeding the threshold value.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method of manufacturing an electronic device, comprising:
obtaining first electrical properties of a plurality of dies by a first test;
selecting a first group of the plurality of dies based on the first electrical properties of the plurality of dies;
treating the first group of the plurality of dies; and
mounting the plurality of dies to a carrier.

2. The method of claim 1, wherein the plurality of dies comprise a second group, and the second group of plurality of dies is not treated.

3. The method of claim 2, wherein selecting the first group of the plurality of dies comprises:
obtaining a first threshold value based on the first electrical properties,
wherein the first electrical properties of the first group exceed the first threshold value.

4. The method of claim 3, further comprising:
obtaining modified electrical properties of the first group and second electrical properties of the second group of the plurality of dies by a second test.

5. The method of claim 4, further comprising:
determining that the first group of the plurality of dies is re-treated based on the second electrical properties.

6. The method of claim 4, wherein the first test and the second test are performed at different temperatures.

7. The method of claim 4, further comprising:
grouping the first group of the plurality of dies into a third group and a fourth group; and
re-treating the third group of the plurality of dies.

8. The method of claim 7, wherein the fourth group of the plurality of dies is not re-treated.

9. The method of claim 7, further comprising:
obtaining a second threshold value based on the second electrical properties.

10. The method of claim 1, wherein the plurality of dies are singulated.

11. The method of claim 1, wherein the plurality of dies are disposed within a wafer.

12. The method of claim 1, further comprising:
obtaining locations of the first group of the plurality of dies of a first wafer; and
modifying process conditions of a process performed on a second wafer based on the locations of the first group of the plurality of dies.

13. The method of claim 1, wherein the plurality of dies comprises a silicon carbide metal-oxide-semiconductor field effect transistor.

14. The method of claim 1, wherein treating the first group of the plurality of dies comprises treating active surfaces of the first group of the plurality of dies.

15. The method of claim 1, wherein treating the first group of the plurality of dies comprises treating backside surfaces of the first group of the plurality of dies.

16. The method of claim 1, wherein a treatment configured to treat the first group of the plurality of dies is performed on a wafer.

17. The method of claim 1, wherein a treatment configured to treat the first group of the plurality of dies is performed on a singulated die.

18. A method of manufacturing an electronic device, comprising:
obtaining electrical properties of a plurality of dies;
obtaining threshold values based on the electrical properties; and
modifying at least one of the electrical properties of a first group of the plurality of dies when the at least one of the electrical properties exceeds a corresponding one of the threshold values.

19. The method of claim 18, wherein the electrical properties comprises on-resistance and threshold voltage.

20. The method of claim 18, wherein the corresponding one of the threshold values depends on an average and a standard deviation of the at least one of the electrical properties.
